(19) United States
(12) Patent Application Publication
(10) Pub. No.: US 2005/0041488 A1
(43) Pub. Date: Feb. 24, 2005

(54) Electro-optical device, method for driving the electro-optical device, and electronic apparatus including the electro-optical device

(75) Inventors: Akihiko Ito, Nagano-ken (JP); Katsutoshi Ueno, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/892,358

(22) Filed: Jul. 16, 2004

(30) Foreign Application Priority Data
Jul. 22, 2003 (JP) 2003-199918

(51) Int. Cl. G11C 8/00

(52) U.S. Cl. 365/199

(57) ABSTRACT

To reduce vertical crosstalk and thereby enhance or improve image quality in an electro-optical device employing time-division driving. In a predetermined period, a corrective voltage Vamd with a predetermined voltage level and time-series data voltages V(1,1) to V(3,1) are outputted to an output line DO1. The corrective voltage Vamd is applied simultaneously to data lines X1 to X3 connected to the output line DO1. The time-series data voltages V(1,1) to V(3,1) are time-divisionally separated into segments and the segmented data voltages V(1,1) to V(3,1) are allocated to any of the data lines X1 to X3.

### BACKGROUND OF THE INVENTION

1. Field of Invention

The present invention relates to an electro-optical device, a method for driving the electro-optical device, and an electronic apparatus including the electro-optical device. More particularly, the invention relates to a technique to reduce vertical crosstalk encountered in time-division driving in the electro-optical device.

2. Description of Related Art

In related art electro-optical devices, data lines and pixel rows are capacitively coupled through parasitic capacitance that is present between the data lines and the pixel rows. A data voltage defining the shades of the pixels is applied to the data lines and the pixel rows are connected to the data lines. When the voltage applied to the data lines varies over time, vertical crosstalk, that is, unevenness of image display along the data lines, may occur due to the capacitive coupling or the like in line sequential scanning of scanning lines. Furthermore, the voltage held at the pixels varies over time due to leakage current encountered when pixel transistors are turned off. The amount of change in voltage at the pixels depends on the difference between the voltage at the data lines and the voltage applied to the pixels. The voltage held at the pixels changes as the voltage applied to the data lines varies over time, resulting in vertical crosstalk. For example, the aforementioned vertical crosstalk occurs typically when a black rectangular window is displayed in the center of a gray background in an electro-optical device which includes liquid crystal that is driven by inverting the voltage polarity per frame in a normally white mode. For the group of data lines disposed at the right and left regions outside the black window, the voltage applied to the data lines is not changed but fixed. Thus, the shades of the pixel rows corresponding to these data lines are gray. By contrast, for the group of data lines in the center region corresponding to the black window, when the scanning line for the top of the window is selected, the voltage decreases (or increases), i.e., the voltage level is changed from gray to black while the scanning line corresponding to the bottom of the window is selected, the voltage increases (or decreases), i.e., the voltage level is changed from black to gray. Furthermore, the voltage applied to the group of data lines disposed at the right and left regions outside the black window is different from the voltage applied to the group of data lines in the center region corresponding to the black window. This difference in voltage, in turn, alters the amount of change in voltage held at pixels due to leakage current. Therefore, data written on the corresponding pixel rows, that is, the voltage applied to the liquid crystal layer, varies. Accordingly, the color is blacker than the gray in the area above the black window, whereas the color is whiter than the gray in the area below the black window.

To reduce the aforementioned vertical crosstalk, for example, Japanese Unexamined Patent Application Publication No. 6-34941 discloses a method for driving an electro-optical device in which a voltage with inverted polarity from that of the data voltage is applied to data lines prior to the application of the data voltage during a horizontal scanning period.

Japanese Unexamined Patent Application Publication No. 11-327518 and Japanese Unexamined Patent Application Publication No. 2001-134245 disclose electro-optical devices where an active matrix display employs time-division driving in order to reduce the number of output pins in a driver IC and therefore provide a sufficient pitch between the output pins. Time-division driving is a technique to separate time-series data for a plurality of pixels, which is outputted from a higher-rank circuit such as a driver IC, into time-sharing segments and to allocate the segmented data to respective data lines.

### SUMMARY OF THE INVENTION

Exemplary embodiments of the present invention reduce vertical crosstalk in an electro-optical device employing time-division driving to thereby enhance display quality.

Exemplary embodiments of the invention address the aforementioned and/or other problems. According to a first exemplary aspect of the present invention, an electro-optical device includes a plurality of pixels provided at crosspoints of a plurality of scanning lines and a plurality of data lines, a plurality of output lines correspond to the plurality of data lines, and a time-division circuit. A corrective voltage with a predetermined voltage level and time-series data voltages are outputted to the plurality of output lines during a predetermined period. The time-division circuit simultaneously applies the corrective voltage to the plurality of data lines and separates the time-series data voltages into time-sharing segments to allocate the segmented data voltages to any of the plurality of data lines, the time-sharing segmented data voltages define the shades of the pixels.

According to a second exemplary aspect of the present invention, a method for driving an electro-optical device includes outputting a corrective voltage with a predetermined voltage level to a plurality of output lines in part of a period during which one scanning line is selected. Further, the exemplary aspect includes supplying the corrective voltage simultaneously to a plurality of data lines, the plurality of output lines corresponding to the plurality of data lines. Further, time-series data voltages are outputted to the plurality of output lines after the corrective voltage is outputted to the plurality of output lines, in part of the period during which the scanning line is selected. The time-series data voltages are separated into time-sharing segments to allocate the segmented data voltages to any of the plurality of data lines, the time-sharing segmented data voltages defining the shades of pixels.

According to the first and second exemplary aspects of the present invention, the corrective voltage is independent of the shades of pixels to be displayed, or substantially the average of the data voltages to be applied to the data lines to which the corrective voltage is simultaneously applied. Furthermore, preferably, the order in which the segmented data voltages are allocated to the plurality of data lines is reversed every predetermined period.

According to a third exemplary aspect of the present invention, an electronic apparatus includes the electro-optical device according to the first exemplary aspect of the invention.

### BRIEF DESCRIPTION OF THE DRAWINGS

FIG. 1 is a schematic that shows an electro-optical device according to an exemplary embodiment of the present invention;

FIG. 2 is a schematic that shows equivalent circuit of a pixel including liquid crystal according to an exemplary embodiment of the present invention;

FIG. 3 is a schematic that shows a driver IC according to an exemplary embodiment of the present invention;

FIG. 4 is a timing chart for time-division driving according to a first exemplary embodiment;

FIG. 5 is a schematic that shows a driver IC according to a second exemplary embodiment;

FIG. 6 is a timing chart for time-division driving according to a third exemplary embodiment;

FIG. 7 is a timing chart for time-division driving according to a fourth exemplary embodiment;

FIG. 8 is a schematic that shows an electro-optical device according to a fifth exemplary embodiment; and

FIG. 9 is a timing chart according to the fifth exemplary embodiment.

### DETAILED DESCRIPTION OF PREFERRED EMBODIMENTS

[First Exemplary Embodiment]

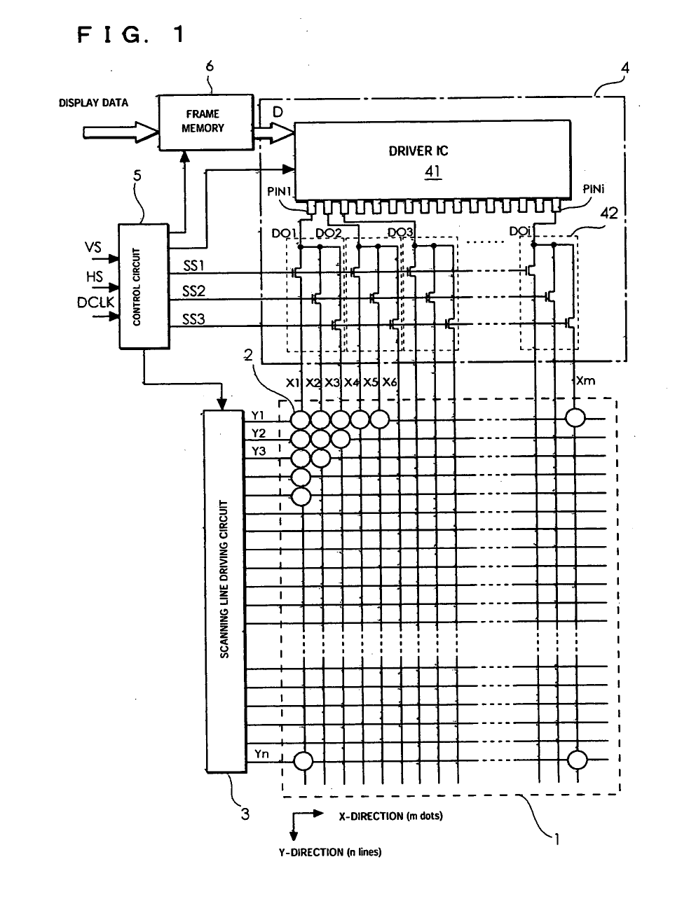

FIG. 1 is a schematic that shows an electro-optical device according to an exemplary embodiment of the present invention. A display unit 1 is an active matrix display panel including liquid crystal elements that are driven by switching elements, such as thin film transistors (TFTs), for example. In the display unit 1, m-dots by n-lines of pixels 2 are arranged in a matrix (two-dimensionally). Further, n scanning lines Y1-Yn are extended along the row direction (x-direction) and m data lines X1-Xm are extended along the column direction (Y-direction). Pixels 2 are arranged at the respective crosspoints of the scanning lines Y1-Yn and the data lines X1-Xm. In the following description, a given pixel 2 in the display unit 1 is defined by the crosspoint of the data line X and the scanning line Y using indexes 1 to m for the data line X and 1 to n for the scanning line Y and is represented as (1-m, 1-n). For example, the far top left pixel 2 is represented as (1,1), while the far bottom right pixel 2 is represented as (m, n).

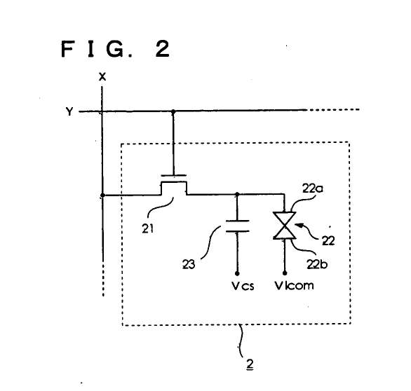

FIG. 2 is a schematic that shows an equivalent circuit for the pixel 2 including liquid crystal. The pixel 2 is composed of a thin film transistor (TFT) 21 serving as a switching element, a liquid crystal capacitor 22, and a storage capacitor 23. A source of the TFT 21 is connected to one data line X and a gate of the TFT 21 is connected to one scanning line Y. The sources of the TFTs 21 in the pixels 2 arranged in the same row are connected to the same data line X. The gates of the TFTs 21 in the pixels 2 arranged in the same row are connected to the same scanning line Y. The drain of the TFT 21 is connected to both the liquid crystal capacitor 22 and the storage capacitor 23, which are arranged in series. The liquid crystal capacitor 22 is composed of a pixel electrode 22a, an opposite electrode 22b, and a liquid crystal layer interposed between the pixel electrode 22a and the opposite electrode 22b. The storage capacitor 23 is disposed between the pixel electrode 22a and a common capacitor electrode (not shown). Voltage Vcs is applied to the storage capacitor 23 which suppresses leakage of electric charge stored at the liquid crystal layer. Data voltage V is applied to the pixel electrode 22a through the TFT 21, and, in response to the voltage applied to the pixel electrode 22a, the liquid crystal capacitor 22 and the storage capacitor 23 are charged or discharged. Therefore, the transmittance of the liquid crystal layer is defined by the potential difference between the pixel electrode 22a and the opposite electrode 22b (the voltage applied to the liquid crystal), thus specifying the shade of the pixel 2.

The pixels 2 are driven by alternating driving in which the voltage polarity is inverted at predetermined intervals in order to make the liquid crystal last long. The voltage polarity is defined by the direction of an electric field applied to the liquid crystal layer, that is, the polarity of the voltage applied to the liquid crystal layer (positive or negative). According to the present exemplary embodiment, a common DC driving method is employed. This driving method is a type of alternating driving. In accordance with this exemplary method, a voltage Vlcom, which is applied to the opposite electrode 22b, and the voltage Vcs, which is applied to the common capacitor electrode, are fixed, while the polarity of the pixel electrode 22a is inverted.

A control circuit 5 synchronously controls a scanning line driving circuit 3, a data line driving circuit 4, and a frame memory 6, in response to external signals, such as a vertical synchronizing signal Vs, a horizontal synchronizing signal Hs, and a dot clock signal DCLK, which are inputted from an external device (not shown). Under this synchronous control, the scanning line driving circuit 3 and the data line driving circuit 4 work together to control the image displayed on the display unit 1. According to this exemplary embodiment, in order to reduce flickering by means of high-speed displaying, the refresh rate (vertical synchronizing frequency) is 120 Hz, which is almost twice as fast as the typical refresh rate. With this refresh rate, one frame (1/60 sec), which is defined by the vertical synchronizing signal Vs, is composed of two fields and line sequential scanning is performed twice in one frame.

The scanning line driving circuit 3 is mainly composed of a shift register and an output circuit and sequentially selects one scanning line Y among the scanning lines Y1 to Yn every horizontal scanning period (1H) by outputting a scanning signal SEL to the target scanning line Y. The horizontal scanning period (1H) corresponds to a period during which one scanning line Y is selected. The scanning signal SEL takes two voltage levels: a high-level voltage (H-level) and a low-level voltage (L-level). The scanning line Y corresponding to a pixel row subjected to data writing takes an H-level and the other scanning lines Y take L-levels. In response to the scanning signal SEL, pixel rows subjected to data writing are sequentially selected one-by-one and the data written to pixels 2 is retained for one field.

The frame memory 6 has at least a memory space for m-by-n bits. This memory space defines the resolution of the display unit 1. The frame memory 6 stores and retains the display data, which is inputted from a higher-rank device, for each frame. The control circuit 5 controls data writing/reading to/from the frame memory 6. Display data D defines the shades of the pixels 2. For example, the display data D is composed of six bits, D0 to D5 and defines 64 shades. The display data D read out from the frame memory 6 is transferred to the data line driving circuit 4 in series through a 6-bit bus.

The data line driving circuit 4, which is disposed below the frame memory 6, works with the scanning line driving circuit 3 to output data for the pixel row subjected to data writing simultaneously to the data lines X1 to Xm. The data line driving circuit 4 is composed of a driver IC 41 and a time-division circuit 42, as shown in FIG. 1. The driver IC 41 is provided separately from the display panel including the pixels 2 arranged in matrix. The driver IC 41 includes i output pins PIN1 to PINi to which output lines DO1 to DOi are connected. The time-division circuit 42 is composed of, for example, polycrystalline silicon thin film transistors and is integrally formed with the display panel in order to reduce the manufacturing costs.

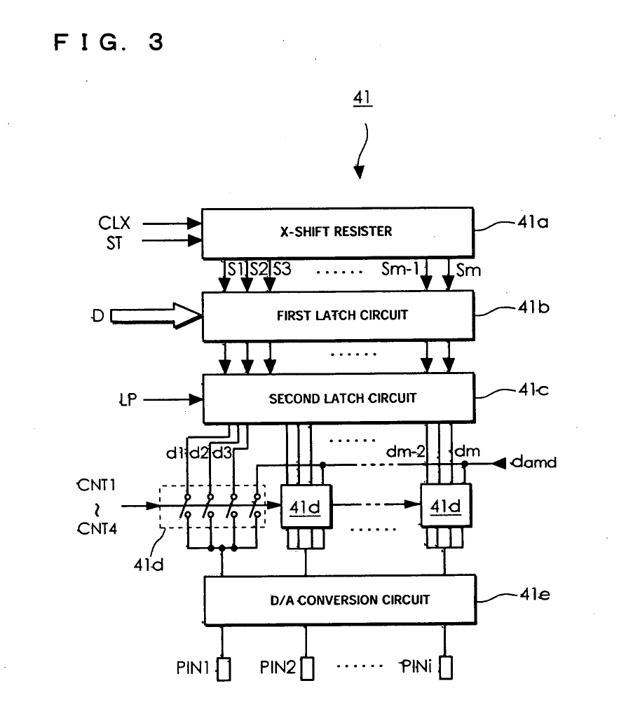

The driver IC 41 simultaneously outputs data for the pixel row subjected to data writing this time and latches, pixel-by-pixel in order, data for the pixel row subjected to data writing next time. FIG. 3 is a block diagram of the driver IC 41. The driver IC 41 primarily includes circuits such as an X-shift register 41a, a first latch circuit 41b, a second latch circuit 41c, switching groups 41d, and a D/A conversion circuit 41e. In 1H, first of all, a start signal ST is supplied to the X-shift register 41a, which then transfers the start signal ST in response to a clock signal CLX and assigns one of latch signals S1 to Sm to an H-level and the other latch signals S1 to Sm to an L-level. The first latch circuit 41b sequentially latches m-pieces of the 6-bit data D which are supplied as serial data, when the voltage of the latch signals S1 to Sm falls. The second latch circuit 41c simultaneously latches the data D, which has been latched by the first latch circuit 41b, when the voltage of a latch pulse LP falls. In the next 1H, the m-pieces of the latched data D are outputted from the second latch circuit 41c in parallel, as digital data signals d1 to dm.

Data signals d1 to dm are grouped to time-series data for three pixels by, for example, m/3 namely, i switching groups 41d each provided for every three data lines. Although each of the switching groups 41d is illustrated to include four switches in FIG. 3, in practice, each switching group 41d includes four subgroups, each having six switches for six bits. Six switches in one subgroup operate in the same manner and are therefore described as one switch in the following description.

Corrective data damd and the data signals, e.g., d1 to d3, for three pixels are inputted to each of the switching groups 41d, the data signals being outputted from the second latch circuit 41c. The corrective data damd is digital data that defines the voltage level of a corrective voltage Vamd, which will be described below. Current supply to the four switches in the switching group 41d is controlled by any of four control signals CNT1 to CNT4. These four switches in the switching group 41d are offset and sequentially turned on one-by-one at an offset timing. Accordingly, in 1H, a series of the corrective data damd and the data signals d1, d2, and d3 for three pixels are outputted from the switching group 41d time-divisionally, in the order of damd, d1, d2 and d3.

The D/A conversion circuit 41e converts a series of digital data, which are outputted from each of the switching groups 41d, into analog data (voltage). As a result, the corrective data damd is converted into the corrective voltage Vamd. The time-series data signals d1 to dm grouped for every three-pixel unit are converted into data voltages and outputted from the output pins PIN1 to PINi in a time-sequential manner.

As shown in FIG. 1, the output pins PIN1 to PINi in the driver IC 41 are connected to any of output lines DO1 to DOi. A group of three neighboring data lines X is associated with one output line DO. The time-division circuit 42 is provided for each output line between the output line DO and the group of three data lines X. Each of the time-division circuits 42 has three selection switches corresponding to the number of data lines X in one group. Current supply to the selection switches is controlled by any of selection signals SS1 to SS3 outputted from the control circuit 5. The selection signals SS1 to SS3 define the periods during which the selection switches are on in one group of three data lines X and are synchronized with the output of the time-series signals from the driver IC 41. Further, i-pieces of the time-division circuit 42 all have the same structure and operate simultaneously with each other. Thus, the output line DO1, which outputs data voltages V1 to V3, is described below as an example.

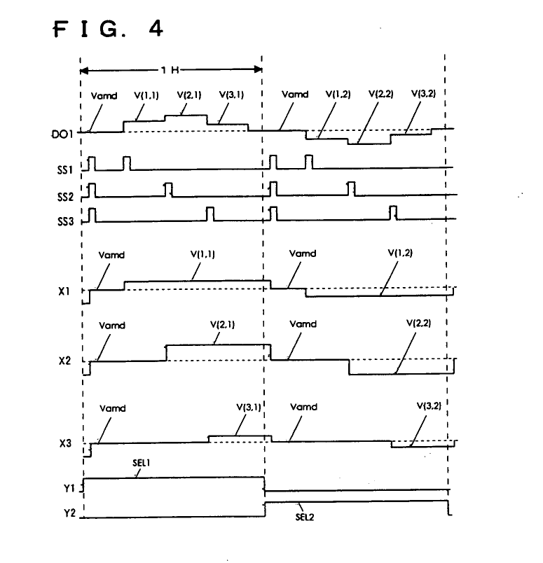

FIG. 4 is a timing chart of time-division driving according to a first exemplary embodiment. The far left time-division circuit 42 connected to the output line DO1, shown in FIG. 1, supplies the corrective voltage Vamd, which is outputted to the output line DO1, to the three data lines X1 to X3 simultaneously. Subsequently, the time-division circuit 42 separates the time-series data voltages V1 to V3 for three pixels into time-sharing segments and the segmented data voltages V1 to V3 are allocated to any of the data lines X1 to X3. More specifically, a scanning signal SEL1 is switched to an H-level and thus the top scanning line Y1 is selected during the first 1H in a field. In the first 1H, first, the corrective voltage Vamd and then the data voltages V1 to V3 for three pixels are outputted to the output line DO1, the three pixels corresponding to the crosspoints of the data lines X1 to X3 and the scanning line Y1, that is, V(1,1), V(2,1), and V(3,1) in this 1H.

When the corrective voltage Vamd is outputted to the output line DO1, the three selection signals SS1 to SS3 are simultaneously switched to an H-level, and thus the three switches in the time-division circuit 42 are turned on simultaneously. As a result, the corrective voltage Vamd outputted to the output line DO1 is applied to the data lines X1 to X3 simultaneously. That is, the data lines X1 to X3 are charged or discharged by the corrective voltage Vamd in advance of the application of the data voltages V(1,1), V(2,1), and V(3,1). The corrective voltage Vamd is used to reduce the vertical crosstalk and is fixed to 0 V in this embodiment.

Then, when the data voltage V(1,1) is outputted to the output line DO1, the selection signal SS1 is exclusively switched to an H-level and the switch corresponding to the data line X1 in the time-division circuit 42 is turned on. Therefore, the data voltage V(1,1), which is outputted to the output line DO1, is applied to the data line X1 and, in response to this data voltage V(1,1), data is written to the pixel (1,1). While the output line DO1 is supplied with the data voltage V(1,1), the switches for the data lines X2 and X3 are kept off so that the data lines X2 and X3 are supplied with the corrective voltage Vamd. (In practice, however, the voltage for the data lines X2 and X3 drops off in process of time due to leakage.)

Next, when the data voltage V(2,1) is outputted to the output line DO1, the selection signal SS2 is exclusively switched to an H-level and thus the switch for the data line X2 in the time-division circuit 42 is turned on. Therefore, the data voltage V(2,1), which is outputted to the output line DO1, is applied to the data line X2. In response to the data voltage V(2,1), data is written to a pixel (2,1). While the output line DO1 is supplied with the data voltage V(2,1), the switches for the data lines X1 and X3 are kept off and thus the data line X1 is supplied with the data voltage V(1,1) and the data line X3 is supplied with the corrective voltage Vamd.

Finally, when the data voltage V(3,1) is outputted to the output line DO1, the selection signal SS3 is exclusively switched to an H-level and thus the switch for the data X3 in the time-division circuit 42 is turned on. Therefore, the data voltage V(3,1), which is outputted to the output line DO1, is applied to the data line X3. In response to the data voltage V(3,1), data is written to a pixel (3,1). While the output line DO1 is supplied with the data voltage V(3,1), the switches for the data lines X1 and X2 are kept off and thus the data line X1 is supplied with the data voltage V(1,1) and the data line X2 is supplied with the voltage V(2,1).

In the next 1H, the scanning signal SEL2 is switched to an H-level and the second scanning line from the top, Y2, is selected. In this 1H, the corrective voltage Vamd is outputted to the output line DO1 and, subsequently, data voltages V1 to V3 for three pixels are sequentially outputted, the three pixels corresponding to the crosspoints of the data lines X1 to X3 and the scanning line Y2, i.e., V(1,2), V(2,2), and V(3,2) in this 1H. The process in the second 1H is the same as in the first 1H except that the polarity of the voltage outputted to the output line DO1 is inverted. In the second 1H, the corrective voltage Vamd is simultaneously applied to the data lines X1 to X3 and the time-series data voltages V(1,2), V(2,2), and V(3,2) are separated into segments and the segmented data voltages V(1,2), V(2,2), and V(3,2) are allocated to the data lines X1 to X3. In the subsequent 1Hs, the same processes are conducted until the bottommost scanning line Yn is selected. In these processes, the polarity of voltage is inverted every 1H and the corrective voltage Vamd is simultaneously applied to data lines and then the data voltages V1 to V3 are sequentially allocated to respective data lines one-by-one up to the last scanning line. In the process shown in FIG. 4, the polarity of the voltage outputted to the output line DO1 is inverted every 1H. Alternatively, the polarity may be inverted every field or frame. In this case, the time-division driving described in the above exemplary embodiment can also be performed.

For the output line DO2, the same process used with the output line DO1 is performed except that voltages V4 to V6 are allocated to the data lines X4 to X6. For other output lines DO3 to DOi, the same process used with the output lines DO1 and DO2 is conducted and their respective voltages are allocated to their respective data lines. The aforementioned processes for the output lines DO1 to DOi are simultaneously conducted.

As described above, according to the first exemplary embodiment, during a predetermined period, e.g., 1H in this exemplary embodiment, the corrective voltage Vamd with a predetermined voltage level and the time-series data voltages V1 to V3 are sequentially outputted to the output line DO1 which is associated with a plurality of data lines, for example, X1 to X3. The time-division circuit 42 supplies the corrective voltage Vamd, which is outputted to the output line DO1, to the data lines X1 to X3 simultaneously. The time-division circuit 42 also separates the time-series data voltages V1 to V3, which are outputted to the output line DO1, into time-sharing segments and allocates the segmented data voltages V1 to V3 to any of the data lines X1 to X3. Accordingly, by the application of the corrective voltage Vamd to the data lines X1 to X3, variation in the average voltages for the data lines X1 to X3 is minimized and thus the average voltages become more uniform among the data lines X1 to X3, as compared to when no corrective voltage Vamd is applied.

In accordance with related art, the voltage written to the pixels 2 (voltage applied to the liquid crystal layer) varies in accordance with the change in the voltage of the data lines X because the pixels 2 and the data lines X are capacitively coupled and current leakage is present therebetween. Further in accordance with related art, the vertical crosstalk along the data lines X is a phenomenon attributed to a difference in such a variation of the applied voltage between pixel rows. According to the first exemplary embodiment, in advance of applying the data voltages V, the corrective voltage Vamd is forcibly applied to the data lines X1 to X3 to offset the electric charge they hold, thereby minimizing variation in the average voltages for the data lines X1 to X3. As a result, although the voltages applied to the three pixel rows, which are respectively connected to the data lines X1 to X3, vary in response to the variations in the respective voltages of the data lines X1 to X3, they become less varied to the extent that the average voltages for the data lines X1 to X3 are uniform. According to the exemplary embodiment, the variation range of the voltage applied to the pixel rows becomes uniform, whereby the vertical crosstalk becomes invisible, leading to enhanced or improved display quality.

In the first exemplary embodiment described above, the corrective voltage Vamd is 0 V which is the intermediate value of the data voltages (driving voltages) V. However, the corrective voltage Vamd may be a combination of the voltage of the liquid crystal when its switch is off, namely, an off-voltage (0 V) and the voltage of the liquid crystal when its switch is on, namely, on-voltage (5 V or −5 V), may be the on-voltage (5 V or −5 V), may be the intermediate value of the on-voltage and the off-voltage, or may be substantially the average of the data voltages that are applied to the data lines to which corrective voltage Vamd is simultaneously applied. The actual corrective voltage Vamd is determined depending on the characteristics of the display panel or TFT. Preferably, the corrective voltage Vamd is not associated with the shade of the pixel 2 to be displayed, considering the complexity of the circuit, however, the corrective voltage Vamd may be variably set in accordance with the mean value of the display data D or the like. Alternatively, 0 V and 5 V may be alternated at predetermined intervals, for example, every 1H. The aforementioned variations of the corrective voltage Vamd apply to the other exemplary embodiments described below.

[Second Exemplary Embodiment]

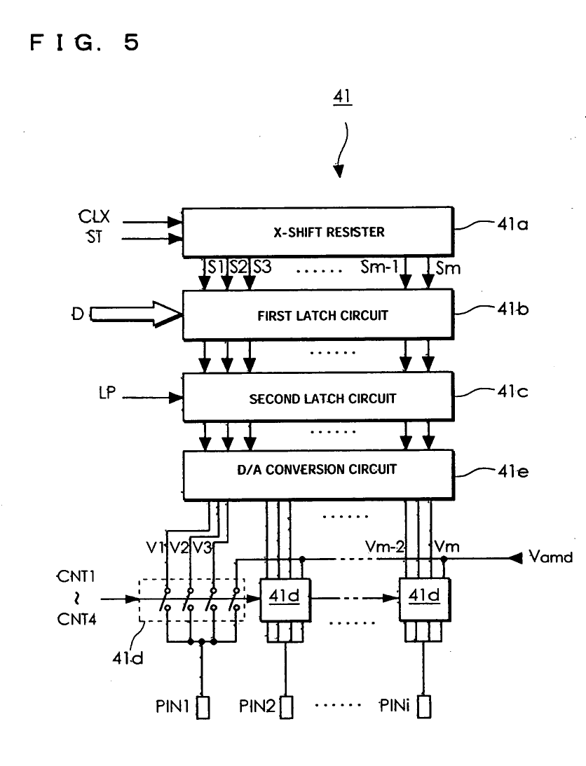

FIG. 5 is a schematic that shows the driver IC 41 according to a second exemplary embodiment. The structure of the driver IC 41 of the second exemplary embodiment shown in FIG. 5 is similar to the first exemplary embodiment shown in FIG. 3 except that the switching groups 41d are disposed below the D/A conversion circuit 41e. Since analog voltage is inputted to the switching groups 41d, each of the switching groups 41d includes four switches, as shown in FIG. 5, unlike the first exemplary embodiment shown in FIG. 3. The rest of the second exemplary embodiment is similar to the first exemplary embodiment and described by referring to the same reference numerals as in the first exemplary embodiment so that description for the same features as those of the first exemplary embodiment is omitted here.

The data voltages, e.g., V1 to V3, for three pixels and the corrective voltage Vamd are inputted to the switching group 41d, the data voltages V1 to V3 being supplied from the D/A conversion circuit 41e. The current supply to the four switches in the switching group 41d is controlled by any of the four control signals CNT1 to CNT4. These four switches in the switching group 41d are offset and then sequentially turned on one by one at an offset timing. Accordingly, the corrective voltage Vamd and the data voltages V1, V2, and V3 for three pixels are time-sequentially outputted through the corresponding output pins in this order during 1H.

According to the second exemplary embodiment, the vertical crosstalk is minimized, leading to enhancement or improvement of the display quality, as in the first exemplary embodiment.

[Third Exemplary Embodiment]

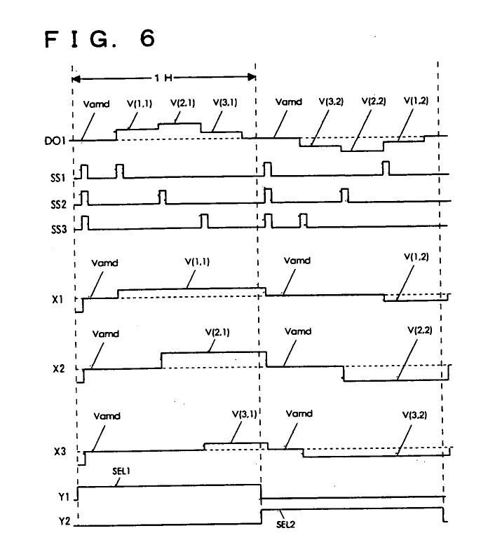

FIG. 6 is a timing chart of time-division driving according to a third exemplary embodiment. In the third exemplary embodiment, during a predetermined period, e.g., 1H, the time-division circuit 42 reverses the order in which the switches constituting the time-division circuit 42 are selected so that the data voltages V are allocated to the data lines X in the reverse order. Accordingly, the order in which the data voltages V are supplied is reversed every 1H, the data voltages V being applied to the output lines DO. Except for this feature, the structure of the third exemplary embodiment is similar to or the same as that of the first exemplary embodiment and its description is omitted here.

In the first 1H, the corrective voltage Vamd and the data voltages V(1,1), V(2,1), and V(3,1) for three pixels are time-sequentially applied to the output DO1 in this order, as in the first exemplary embodiment. Then, after the selection signals SS1 to SS3 are simultaneously switched to an H-level, the selection signals SS1, SS2 and SS3 are exclusively switched to the H-level one-by-one in this order. Accordingly, the corrective voltage Vamd is simultaneously applied to the data lines X1 to X3 while the data voltage V(1,1) is allocated to the data line X1, the data voltage V(2,1) is allocated to the data line X2, and the data voltage V(3,1) is allocated to the data line X3.

In the next 1H, the corrective voltage Vamd and the data voltages V(3,2), V(2,2), and V(1,2) for three pixels are time-sequentially applied to the output line DO1 in this order. Then, after the selection signals SS1 to SS3 are simultaneously switched to an H-level, the selection signals SS3, SS2 and SS1 are exclusively switched to the H-level one-by-one in this order. Accordingly, the corrective voltage Vamd is simultaneously applied to the data lines X1 to X3 while the data voltage V(3,2) is allocated to the data line X3, the data voltage V(2,2) is allocated to the data line X2, and the data voltage V(1,2) is allocated to the data line X1.

According to the third exemplary embodiment, the duration during which the data lines X1 to X3 are kept at the corrective voltage Vamd is uniform among the data lines X1 to X3 so that the display quality is even further enhanced or improved, as compared to the time-division driving shown in FIG. 4. In reference to FIG. 4, the durations during which the data lines X1 to X3 are kept at the corrective voltage Vamd differ among the data lines X1 to X3 and the durations for the data lines X1, X2, and X3 become longer in this order. In contrast, according to this exemplary embodiment, the order in which the data voltages V1 to V3 are allocated to the data lines X1 to X3 is reversed every 1H so that the durations during which the data lines X1 to X3 are kept at the corrective voltage Vamd become uniform among the data lines X1 to X3. Accordingly, the difference in the average voltages for the data lines X1 to X3 is effectively minimized, and the variation in data written on pixel rows to which these data lines X1 to X3 are connected becomes even more uniform. In other words, by averaging the durations during which the data lines are kept at the corrective voltage Vamd among the data lines X1 to X3, it is possible to suppress uneven distribution of the crosstalk cancellation effect which works on the data lines X1 to X3 respectively.

In this exemplary embodiment, the order in which the data voltages V to the data lines X are allocated is reversed every 1H, that is, every period during which one scanning line Y is selected. Alternatively, the order may be reversed every field, i.e., every period during which all the scanning lines Y1 to Yn are selected or may be reversed every alternate 1H and field.

[Fourth Exemplary Embodiment]

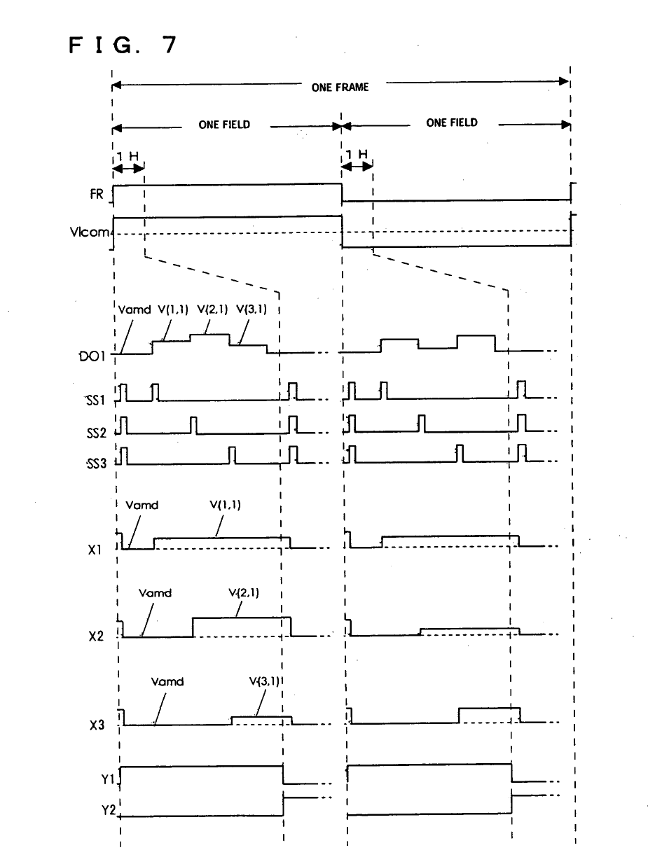

FIG. 7 is a timing chart for time-division driving according to a fourth exemplary embodiment. The present exemplary embodiment is related to a common AC driving method, a type of alternate driving for driving crystal liquid, in which the voltage Vlcom applied to the opposite electrode 22b varies. The polarity of the voltage Vlcom is defined by a polarity directing signal FR and is inverted every field. The corrective voltage Vamd is maintained at approximately 0 V, regardless of the inversion of the polarity.

According to the present exemplary embodiment, output of the corrective voltage Vamd to the data lines reduces the vertical crosstalk, leading to improved display quality, as in the other exemplary embodiments described above.

[Fifth Exemplary Embodiment]

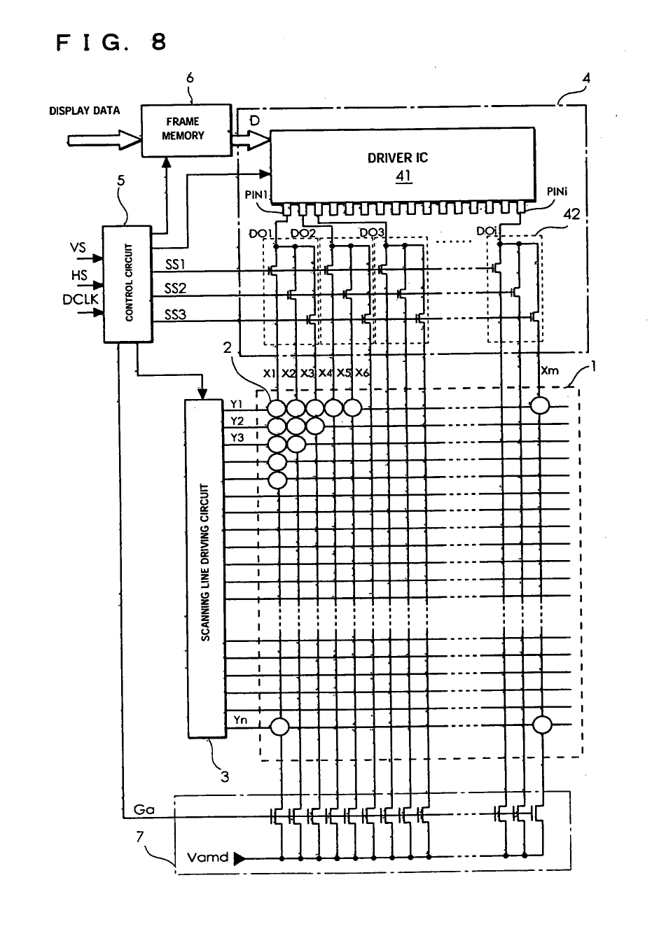

FIG. 8 is a schematic that shows an electro-optical device according to a fifth exemplary embodiment of the present invention. In this fifth exemplary embodiment, instead of the data line driving circuit 4, a corrective voltage circuit 7 supplies the corrective voltage Vamd to the data lines X1 to Xm. In this case, the data line driving circuit 4 of the fifth exemplary embodiment is not required to have a function to generate and supply the corrective voltage Vamd.

The corrective voltage circuit 7 is disposed so as to face the data line driving circuit 4 (below the display unit 1 in the drawing). The corrective voltage circuit 7 is composed of a plurality of switching transistors that are provided every data line. Each switching transistor is connected to the data line X at one end thereof and the corrective voltage Vamd is commonly applied to the other end thereof. Current supply to these switching transistors is commonly controlled by a corrective voltage selection signal Ga from the control circuit 5.

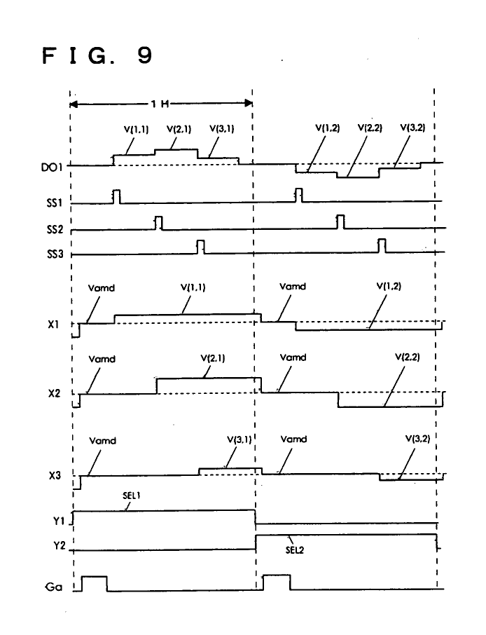

FIG. 9 is a timing chart according to the present exemplary embodiment. When the corrective voltage circuit 7 supplies the corrective voltage Vamd, the timing when the corrective voltage Vamd is applied is the same as that in the other exemplary embodiments described above. Prior to the allocation of time-series data by the time-division circuit 42, the corrective voltage selection signal Ga is switched to an H-level. Therefore, all the switching transistors in the corrective voltage circuit 7 are simultaneously turned on so that the corrective voltage Vamd is applied to the data lines X1 to Xm and is thus written to the pixels. Subsequently, the time-series data is allocated by the time-division circuit 42, while the corrective voltage selection signal Ga is maintained at the L-level. Therefore, during the allocation of data, all the switching transistors in the corrective voltage circuit 7 are off and thus the supply of the voltage from the corrective voltage circuit 7 is interrupted.

According to the exemplary embodiments of the present invention, the corrective voltage circuit 7 supplies the corrective voltage Vamd so that the vertical crosstalk is reduced and thereby the display quality is improved even without an extra circuit in the data line driving circuit 4.

In the above-described exemplary embodiments, the time-series data is segmented into three by the time-division circuit 42, but it may be segmented into any numbers, such as two, four, five, six, seven, eight . . . , and the time-division driving can operate in the same manner.

In the above-described exemplary embodiments, the electro-optical device is composed of liquid crystal elements. The present invention is not limited thereto and may be applied to an organic electroluminescent element, a digital micromirror device (DMD), a field emission display (FED), or a surface conduction electron-emitter display (SED).

The electro-optical device according to the above-described exemplary embodiments may be included in various electronic apparatuses such as televisions, projectors, cellular phones, mobile terminals, mobile computers, or personal computers. Electronic apparatuses including the electro-optical device of the present invention have a higher marketability and improved appeal to the market.

According to the exemplary embodiments of the electro-optical device utilizing time-division driving of the present invention, the vertical crosstalk is reduced, leading to enhanced or improved display quality.

1. An electro-optical device, comprising:
a plurality of scanning lines;
a plurality of data lines;
a plurality of pixels provided at crosspoints of the plurality of scanning lines and the plurality of data lines;
a plurality of output lines to which a corrective voltage with a predetermined voltage level and time-series data voltages are outputted during a predetermined period, the plurality of output lines corresponding to the plurality of data lines; and
a time-division circuit to simultaneously apply the corrective voltage to the plurality of data lines and separate the time-series data voltages into time-sharing segments to allocate the segmented data voltages to any of the plurality of data lines, the segmented data voltages defining shades of the pixels.

2. The electro-optical device according to claim 1, the corrective voltage being independent of the shades of the pixels to be displayed.

3. The electro-optical device according to claim 1, the corrective voltage being substantially an average of the data voltages to be applied to the data lines to which the corrective voltage is simultaneously applied.

4. The electro-optical device according to claim 1, the time-division circuit reversing an order in which the segmented data voltages are allocated to the plurality of data lines every predetermined period.

5. An electronic apparatus, comprising:
the electro-optical device according to claim 1.

6. A method for driving an electro-optical device, comprising:
outputting a corrective voltage with a predetermined voltage level to a plurality of output lines in part of a period during which one scanning line is selected;
supplying the corrective voltage simultaneously to a plurality of data lines, the plurality of output lines corresponding to the plurality of data lines;
outputting time-series data voltages to the plurality of output lines after the corrective voltage is outputted to the plurality of output lines, and in part of the period during which the scanning line is selected; and
separating the time-series data voltages into time-sharing segments to allocate the segmented data voltages to any of the plurality of data lines, the time-sharing segmented data voltages defining the shades of pixels.

7. The method for driving an electro-optical device according to claim 6, the corrective voltage being independent of shades of the pixels to be displayed.

8. The method for driving an electro-optical device according to claim 6, the corrective voltage being substantially an average of the data voltages to be applied to the data lines to which the corrective voltage is simultaneously applied.

9. The method for driving an electro-optical device according to claim 6, the separating the time-series data voltages into time-sharing segments further including reversing the order in which the segmented data voltages are allocated to the plurality of data lines every predetermined period.
